(19) United States
(12) Patent Application Publication
(10) Pub. No.: US 2013/0001728 A1
(43) Pub. Date: Jan. 3, 2013

(54) BACKSIDE ILLUMINATED IMAGE SENSORS WITH VERTICAL LIGHT SHIELDS

(76) Inventor: Giovanni De Amicis, L'Aquila (IT)

(21) Appl. No.: 13/190,389

(22) Filed: Jul. 25, 2011

Related U.S. Application Data
(60) Provisional application No. 61/502,620, filed on Jun. 29, 2011.

(51) Int. Cl. H01L 31/0216; H01L 31/18

(52) U.S. Cl. 257/435; 438/73; 257/E31.121

(57) ABSTRACT

Methods for forming backside illuminated (BSI) image sensors having vertical light shields are provided. Vertical light shields may be configured such that incoming light is blocked from reaching a portion of a pixel array formed on the backside illuminated image sensor. Vertical light shields may include horizontal portions that block direct illumination of dark pixels in the pixel array and vertical portions that block illumination of the dark pixels by reflected light. Vertical light shields may be formed from a dielectric layer, a layer of patterned light shield material formed over the dielectric layer and a passivation layer formed over the patterned light shield material. Vertical light shields may be formed by first etching a vertical trench in a device wafer layer over a portion of the pixel array and filling the vertical trench with light shield material to form the vertical light shield.

This application claims the benefit of provisional patent application No. 61/502,620, filed Jun. 29, 2011, which is hereby incorporated by reference herein in its entirety.

### BACKGROUND

This relates generally to imaging devices, and more particularly, to imaging devices having backside illuminated image sensors with light shields.

Image sensors are commonly used in electronic devices such as cellular telephones, cameras, and computers to capture images. Conventional image sensors are fabricated on a semiconductor substrate using complementary metal-oxide-semiconductor (CMOS) technology or charge-coupled device (CCD) technology. The image sensors may include pixels that include photodiodes and other operational circuitry such as transistors formed in a front surface of the substrate. A dielectric stack is formed on the front surface of the substrate directly on top of the photodiodes. The dielectric stack includes metal routing lines and metal vias formed in dielectric material.

A color filter array is formed over the dielectric stack to provide each pixel with sensitivity to a certain range of wavelengths. Microlenses may be formed over the color filter array. Light enters from a front side of the image sensor (i.e., light enters the microlenses and travels through the color filters into the dielectric stack). An image sensor used in this way is referred to as a frontside illumination (FSI) image sensor. Because the light must pass through the metal routing lines and metal vias of the dielectric stack in an FSI image sensor, internal reflections within the dielectric stack may cause cross-talk between neighboring image sensors. The size of photosensitive elements in an FSI image sensor is limited due to the space required for routing lines, etc. in the dielectric stack in front of the photosensitive elements.

To address these issues, backside illumination (BSI) image sensors have been developed. In conventional BSI image sensors, microlenses may be formed on the back surface of the substrate on the opposite side of the photodiodes from the dielectric stack. In a typical arrangement, a color filter array is formed under the microlenses on the back surface of the substrate to provide each pixel with sensitivity to a certain range of wavelengths. Light enters from the back side of the image sensor (i.e., light enters the microlenses and travels through the color filters onto the photodiodes).

In a conventional BSI image sensor, light blocking materials are horizontally patterned over a fraction of the pixels near the edge of an image sensor. This creates dark pixels (i.e., pixels that are not exposed to direct illumination) for measuring dark currents in the image sensors. Dark currents measured by pixels having the same construction and circuitry as pixels that are exposed to light can be subtracted from image signals produced by light pixels (i.e., pixels that are exposed to light) providing improved sensitivity and noise performance. Typical BSI image sensors using CMOS technology contain at least one interface between dielectric layers that can reflect image light within the image sensor. Image light reflected from dielectric interfaces can be redirected past horizontally patterned light blocking materials and can be absorbed by dark pixels that are not exposed to direct illumination thereby corrupting the dark current measurements. It would therefore be desirable to provide BSI image sensors with improved light blocking for dark pixels.

### BRIEF DESCRIPTION OF THE DRAWINGS

FIG. 1 is a diagram of an illustrative electronic device in accordance with an embodiment of the present invention.

FIG. 2A is a top view of a conventional image sensor having a horizontal light block over a portion of a pixel array.

FIG. 2B is a cross-sectional side view of the conventional image sensor of FIG. 2A along line A of FIG. 2A.

FIG. 3 is a cross-sectional side view of an illustrative backside illumination image sensor before formation of a light shield in accordance with an embodiment of the present invention.

FIG. 4 is a cross-sectional side view of the illustrative image sensor of FIG. 3 after formation of openings for a vertical light shield in accordance with an embodiment of the present invention.

FIG. 5 is a cross-sectional side view of the illustrative image sensor of FIG. 4 after deposition of a dielectric layer for a vertical light shield in accordance with an embodiment of the present invention.

FIG. 6 is a cross-sectional side view of the illustrative image sensor of FIG. 5 after deposition of optical blocking material for a vertical light shield in accordance with an embodiment of the present invention.

FIG. 7 is a cross-sectional side view of the illustrative image sensor of FIG. 6 after formation of openings in an optical blocking material for a vertical light shield in accordance with an embodiment of the present invention.

FIG. 8 is a cross-sectional side view of an illustrative backside illuminated image sensor having a vertical light shield in accordance with an embodiment of the present invention.

FIG. 9 is a top view of an illustrative backside illuminated image sensor having a vertical light shield in accordance with an embodiment of the present invention.

FIG. 10 is a flowchart of illustrative steps involved in forming a backside illuminated image sensor having a vertical light shield in accordance with an embodiment of the present invention.

### DETAILED DESCRIPTION

Digital camera modules are widely used in electronic devices such as digital cameras, computers, cellular telephones, or other electronic devices. These electronic devices may include image sensors that receive incoming light to capture an image. The image sensors may include arrays of image pixels. The pixels in the image sensors may include photosensitive elements such as photodiodes that convert the incoming light into digital data. Image sensors may have any number of pixels (e.g., hundreds or thousands or more). A typical image sensor may, for example, have millions of pixels (e.g., megapixels).

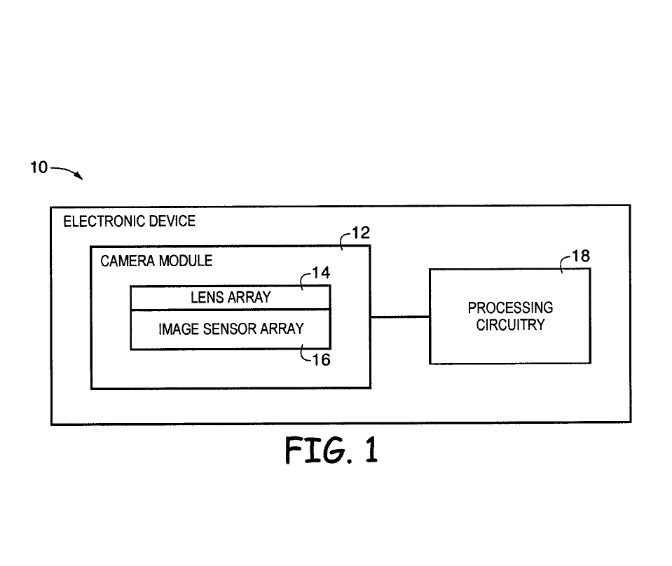

FIG. 1 is a diagram of an illustrative electronic device that uses an image sensor to capture images. Electronic device 10 of FIG. 1 may be a portable electronic device such as a camera, a cellular telephone, a video camera, or other imaging device that captures digital image data. Camera module 12 may be used to convert incoming light into digital image data. Camera module 12 may include an array of lenses 14 and a corresponding array of image sensors 16. Lenses 14 and image sensors 16 may be mounted in a common package and may provide image data to processing circuitry 18. Processing circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be processed and stored using processing circuitry 18. Processed image data may, if desired, be provided to external equipment (e.g., a computer or other device) using wired and/or wireless communications paths coupled to processing circuitry 18.

Image sensor array 16 may contain an array of individual image sensors configured to receive light of a given color by providing each image sensor with a color filter. The color filters that are used for image sensor pixel arrays in the image sensors may, for example, be red filters, blue filters, and green filters. Each filter may form a color filter layer that covers the image sensor pixel array of a respective image sensor in the array. Other filters such as white color filters, dual-band IR cutoff filters (e.g., filters that allow visible light and a range of infrared light emitted by LED lights), etc. may also be used.

The image sensors may be formed on one or more separate semiconductor substrates. With one suitable arrangement, which is sometimes described herein as an example, the image sensors are formed on a common semiconductor substrate (e.g., a common silicon image sensor integrated circuit die). Each image sensor may be identical. Image sensor arrays in which the image sensors are not all identical may be used.

Processing circuitry 18 (e.g., processing circuitry integrated onto sensor array integrated circuit 16 and/or processing circuitry on one or more associated integrated circuits) can select which digital image data to use in constructing a final image for the user of device 10. For example, circuitry 18 may be used to blend image data from red, blue, and green sensors to produce full-color images, may be used to determine image parallax corrections, may be used to produce 3-dimensional (sometimes called stereo) images using data from two or more different sensors that have different vantage points when capturing a scene, may be used to produce increased DOF images using data from two or more image sensors, etc. In some modes of operation, all of the sensors on array 16 may be active (e.g., when determining 3-dimensional image depth information). In other modes of operation (e.g., color imaging), only a subset of the image sensors may be used. Other sensors may be inactivated to conserve power (e.g., their positive power supply voltage terminals may be taken to a ground voltage or other suitable power-down voltage and their control circuits may be inactivated or bypassed).

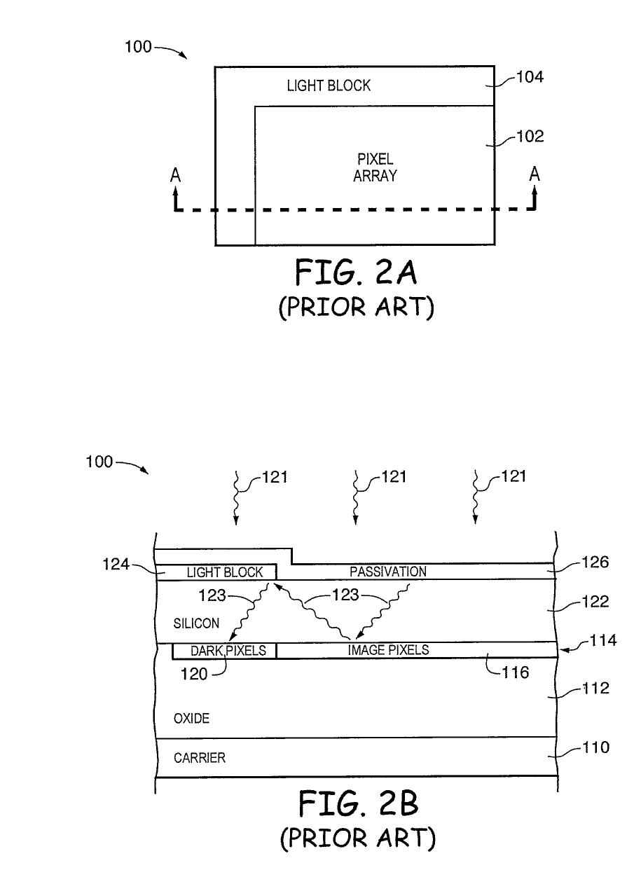

FIG. 2A is a top view of a conventional image sensor having horizontal light blocking structures. As shown in FIG. 2A, image sensor 100 may include an array of image pixels such as pixel array 102 that is partially covered by light blocking material such as light block 104. Covering a portion of pixel array 102 with light block 104 provides pixels in pixel array 102 that are not exposed to direct illumination. Pixels that are not exposed to direct illumination may be used to make measurements of dark currents that are similar to dark currents in light exposed pixels. However, internal reflections within image sensor 100 may allow light to reach pixels that are covered by light block 104 thereby corrupting any dark current measurement made using those pixels. Internal reflections may occur at interfaces between dielectric layers of image sensor 100 as shown in FIG. 2B.

As shown in FIG. 2B, conventional image sensor 100 is formed on a carrier 110. Image sensor 100 is a backside illuminated image sensor that has pixels 114 formed in an oxide layer 112 that is mounted between carrier 110 and a silicon layer 122. Pixels 114 include light exposed pixels 116 (i.e., image pixels), and dark pixels 120 (i.e., pixels that are blocked from direct overhead illumination by horizontal light block 124. Horizontal light block 124 is formed on silicon layer 122 and is covered by passivation layer 126. Incident light 122 is blocked from reaching dark pixels 120 by light block 124. However, reflected light 124 that is reflected at the boundary between silicon layer 122 and oxide layer 112 is able to reach dark pixels 120 and corrupt any dark current measurements made using those pixels.

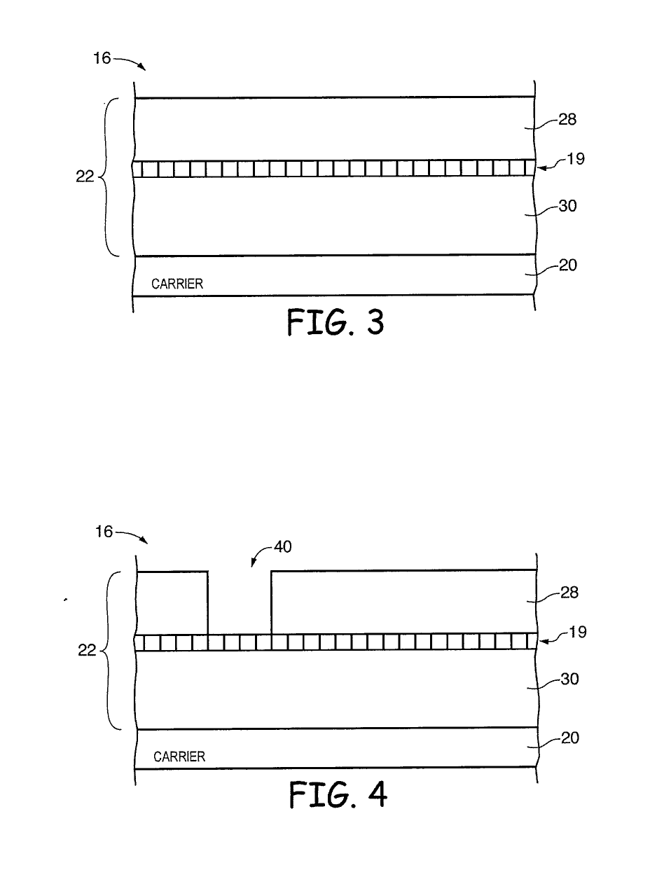

FIG. 3 is a cross-sectional side view of a portion of an illustrative BSI image sensor prior to formation of a vertical light block for forming dark pixels. As shown in FIG. 3, image sensor array 16 may include a carrier layer such as carrier layer 20. Carrier layer 20 may be made from silicon, another material or a combination of other suitable materials. Carrier layer 20 may be mounted to a device wafer such as device wafer 22. Device wafer 22 may be formed from one or more device substrate layers such as device substrate layers 28 and 30. Layers 28 and 30 may be formed from a common dielectric material or may be formed from different materials. In one suitable configuration that is sometimes described herein as an example, device substrate layer 30 (sometimes called device wafer layer 30) may be formed from an oxide material and device substrate layer 28 (sometimes called device wafer layer 28) may be formed from silicon. Device wafer 22 (sometimes referred to herein as device substrate 22) may include an array of pixels such as image pixel array 19. Each pixel in image pixel array 19 may include photosensitive elements (e.g., photodiodes, etc.) and other circuitry such as transistors, charge storage regions, etc.

Each pixel in image pixel array 19 may be covered by one or more microlenses formed in device substrate 22 that focus incoming light onto the photosensitive elements. Each pixel in image pixel array 19 may include color filter elements formed in device substrate 22 (between the photosensitive elements and the microlenses) that control the color of light that is allowed to reach the photosensitive elements. Image pixel array 19 may have color filter elements that all pass a single color of light (e.g., red light, blue light, green light, infrared light, etc.) or may have a patterned array of color filters (e.g., a patterned array of color filters having a Bayer color filter pattern). Image pixel array 19 may include active pixels that are electrically connected to circuitry formed within device wafer 22 and inactive pixels (sometimes called dummy pixels) that are not electrically connected to circuitry formed within device wafer 22. Alternatively, inactive pixels may be electrically connected to circuitry formed within device wafer 22 but may be rendered inactive using external control circuitry.

FIG. 4 is a cross-sectional side view of a portion of an illustrative BSI image sensor during formation of openings in the device wafer for formation of vertical light block for forming dark pixels. As shown in FIG. 4, openings 40 in dielectric layer 28 of device wafer 22 of image sensor array 16 may be formed over a portion of pixel array 19. Openings 40 may be photo-defined, wet etched, dry etched or otherwise patterned in layer 28 of device wafer 22. Openings 40 may be formed at the same time as formation of standard openings in device wafer 22 during formation of electrical bond pads in a standard BSI image sensor process or may be formed in a separate processing step from formation of other openings for BSI image sensor formation.

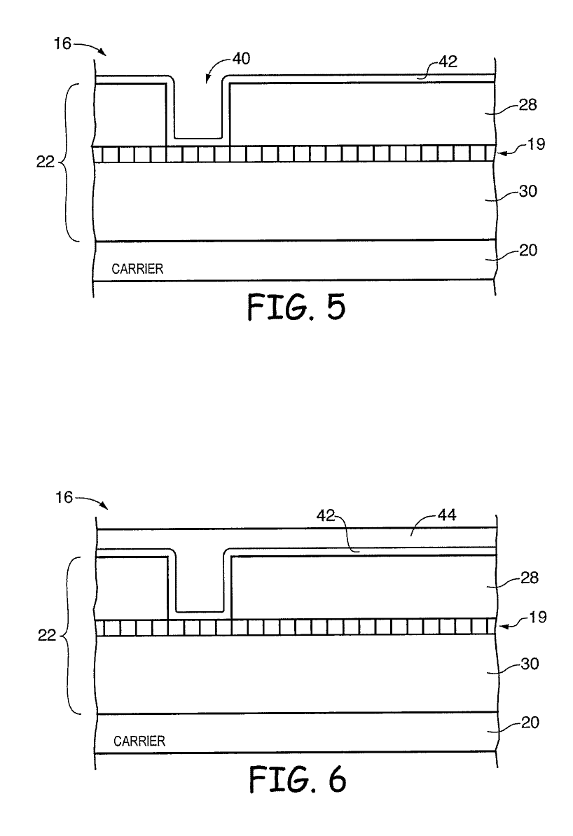

Following formation of openings 40 in layer 28 of device wafer 22, a dielectric layer such as dielectric layer 42 may be deposited on layer 28 covering a portion of layer 28 including inner surfaces of openings 40 as shown in FIG. 5. Dielectric layer 42 may be a spin on dielectric, a chemical vapor deposited dielectric or other dielectric. Dielectric layer 42 may be used to electrically isolate device wafer 22 and a light blocking material to be used in formation of a vertical light shield for image sensor array 16.

Light shield material may be deposited over dielectric layer 42 as shown in FIG. 6. Light shield material 44 may be formed from aluminum, copper, any other metal, or any other suitable light blocking material (e.g., material through which visible light does not pass). Light shield material 44 may be deposited on dielectric layer 42 using any suitable deposition process (e.g., spatter deposition, screen-printing, etc.). Light shield material 44 may be deposited such that light shield material 44 fills opening 40 of FIG. 5. Light shield material 44 may cover a portion of dielectric layer 42 or may cover substantially all of dielectric layer 42. Light shield material 44 may be deposited such that a portion or substantially all of image pixel array 19 is covered by light shield material 44 (see e.g., FIG. 6).

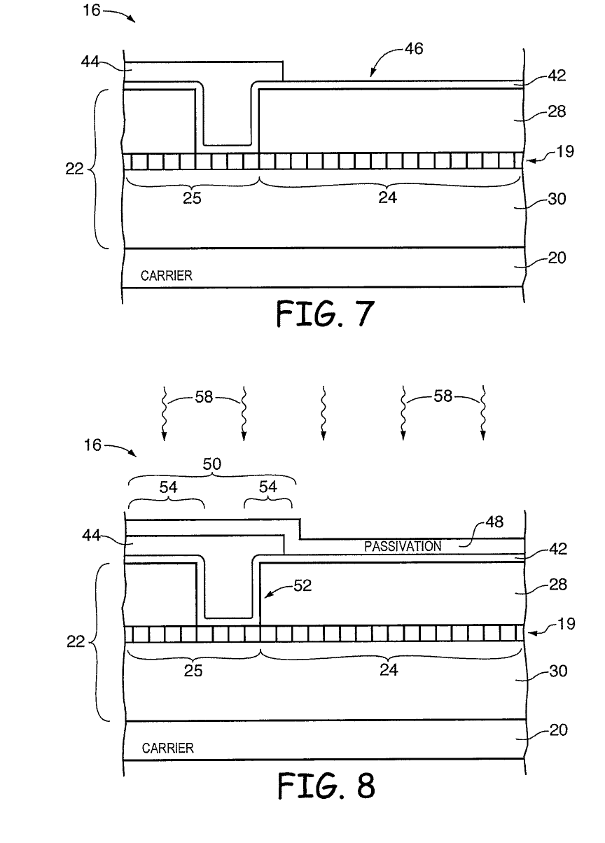

As shown in FIG. 7, light shield material 44 may be patterned to have openings such as openings 46. Openings 46 in light shield material 44 may be formed over a portion of image pixel array 19 so that light pixels 24 of pixel array 19 may be exposed to image light while dark pixels 25 remain shield from image light by light shield material 44. Openings 46 may be formed using any suitable metal patterning and etch process (e.g., a dry etch process).

As shown in FIG. 8, following formation of openings such as opening 46 in light shield material 44, passivation layer 48 may be formed on device wafer 22. Passivation layer 48 may cover substantially all of light shield material 44. Passivation layer 48 may be formed of substantially all pixels of image pixel array 19. Passivation layer 48 may cover any portions of dielectric layer 42 that are not covered by light shield material 44. Passivation layer 48 may be a spin on dielectric, a chemical vapor deposited dielectric or other dielectric. As shown in FIG. 8, after passivation layer 48 has been formed on device wafer 22 of image sensor array 16, image sensor array 16 may be provided with a vertical light shield such as vertical light shield 50. Vertical light shield 50 may have one or more horizontal portions such as horizontal portions 54 and a vertical trench such as vertical trench 52. Vertical trench 52 may be formed in a device substrate layer such as layer 28 of device substrate 22. Layer 28 may be a silicon layer or may be any other dielectric layer. Vertical light shield 50 may include light shield material 44 formed over a dielectric layer such as dielectric layer 42. Dielectric layer 42 may electrically insulate light shield material 44 from layer 28 of device wafer 22. Light shield material 44 may be formed from aluminum, copper, any other metal, or any other suitable light blocking material (e.g., material through which visible light does not pass).

Vertical light shield 50 may include a portion of a passivation layer such as passivation layer 48 that covers device wafer 22. Portions of dielectric layer 42, light shield material 44 and passivation layer 48 may be formed in vertical trench 52. Portions of dielectric layer 42, light shield material 44 and passivation layer 48 may form horizontal portions 54 of vertical light shield 50. Vertical light shield 50 may help block incoming light 58 from reaching dark pixels 25. Vertical portion 52 of vertical light shield 50 may help block light that is reflected within device wafer 22 from reaching dark pixels 25. Dark pixels 25 may be electrically connected to readout circuitry in image sensor array 16 in substantially the same way as light pixels 24 (i.e., pixels that are configured to receive incoming light). Dark pixels 25 may be used to measure dark currents that may be subtracted from signals measured by light pixels 24 during operation of a device of the type shown in FIG. 1. Providing image sensor array 16 with a vertical light shield such as vertical light shield 50 may help image sensor array 16 measure dark currents more accurately providing better noise reduction and sensitivity in measuring light with light pixels 24. Image sensor array 16 may also include inactive or dummy pixels that are electrically connected to readout circuitry or may electrically isolated from readout circuitry associated with image sensor array 16. Inactive pixels may be used to provide image sensor array 16 with uniformly distributed light pixels 24 (e.g., a square array of light pixels) and may include some of dark pixels 25, some of light pixels 24 or some of both light pixels 24 and dark pixels 25. In the example FIG. 8, device wafer 22 of image sensor array 16 includes two device substrate layers 28 and 30 and a carrier wafer such as carrier wafer 20.

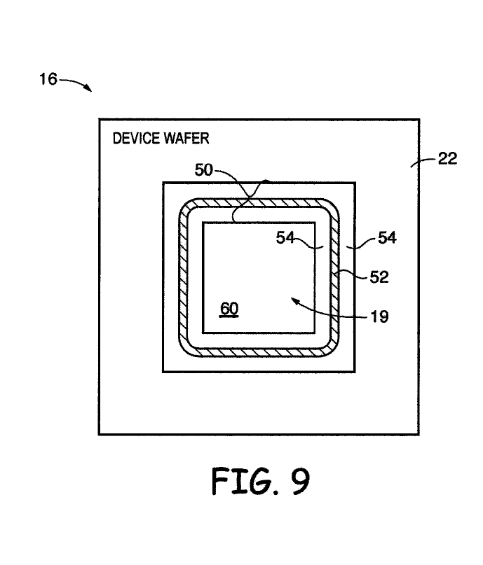

FIG. 9 is a top view of an image sensor array of the type shown in FIG. 8. As shown in FIG. 9, image sensor array 16 includes device wafer 22 having at least one array of image pixels 19 having a region that is exposed to light such as light exposed region 60. Image pixel array 19 may be formed on a single integrated circuit die (e.g., a silicon integrated circuit die). Each pixel in image pixel array 19 may be covered by one or more microlenses formed in device substrate 22 that focus incoming light onto photosensitive elements. Each pixel in image pixel array 19 may include color filter elements formed in device substrate 22 (between the photosensitive elements and the microlenses) that control the color of light that is allowed to reach the photosensitive elements. Image pixel array 19 may have color filter elements that all pass a single color of light (e.g., red light, blue light, green light, infrared light, etc.) or may have a patterned array of color filters (e.g., a patterned array of color filters having a Bayer color filter pattern). Light exposed region 60 may include light pixels such as light pixels 24 of FIG. 8. Portions of image pixel array 19 may be covered by vertical light shield 50. As shown in FIG. 9, vertical light shield 50 may include one or more horizontal portions 54 on either side of a vertical trench such as vertical trench 52. In the example of FIG. 9, vertical light shield 50 covers pixels on four sides of image pixel array 19. This is merely illustrative. Vertical light shield 50 may cover pixels on one side, two sides, three sides or four sides of image pixel array 19.

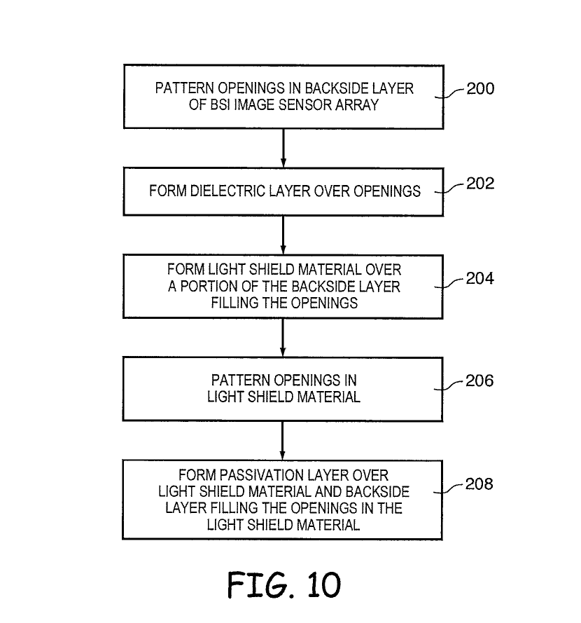

FIG. 10 is a flowchart showing illustrative steps involved in the formation of a backside illuminated image sensor array having a vertical light shield. As shown in FIG. 10, at step 200, openings may be patterned in a backside of a device wafer layer of a backside illuminated image sensor. Openings may be formed over portion of a pixel array already formed on a backside of the image sensor array.

At step 202, a dielectric layer may be formed on the backside of the image sensor array including formation of the dielectric layer on surfaces of the openings.

At step 204, light shield material may be deposited over the dielectric layer on the backside of the image sensor array filling the openings and covering substantially all of the dielectric layer that is formed on the backside of the image sensor array. Light shield material may include aluminum, copper, other metals or any other suitable material that blocks visible light. Light shield material may be deposited using spatter deposition or other suitable deposition methods.

At step 206, openings may be patterned in the light shield material. Openings formed in the light shield material may be formed over the a portion of the pixel array thereby removing the light shield material over that portion and therefore allowing some pixels of the pixel array to be exposed to illumination.

At step 208, a passivation layer may be formed over the light shield material deposited in step 204. Passivation layer material may include any suitable dielectric material. The passivation layer may be formed such that the passivation layer covers substantially all of the light shield material and the dielectric layer. Portions of the passivation layer may cover light pixels that are not shielded by the vertical light shield.

Various embodiments have been described illustrating formation of backside illuminated image sensors having vertical light shields. Vertical light shields may be formed on a backside of a backside illuminated image sensor array. Vertical light shields may be configured such that incoming light in blocked from reaching a portion of a pixel array formed on the backside illuminated image sensor array. Vertical light shields may include horizontal portions that block direct illumination of dark pixels in the pixel array and vertical portions that block reflected illumination of the dark pixels. Vertical light shields may be formed from a dielectric layer, a layer of patterned light shield material formed over the dielectric layer and a passivation layer formed over the patterned light shield material. Vertical light shields may be formed by first etching a vertical opening (trench) in a device substrate layer over a portion of the pixel array. The dielectric layer and the light shield material layer may be formed over the vertical opening such that the light shield material fills the opening. The passivation layer may then be formed over the light shield material filling the opening in the light shield material. The vertical light shield may cover pixels on one edge, on two edges, on three edges, or on all four edges of the pixel array. Pixels that are shielded by vertical light shields may be used to measure dark currents and may provide increased noise control and sensitivity for pixels that measure light signals.

The foregoing is merely illustrative of the principles of this invention which can be practiced in other embodiments.

1. An image sensor configured to capture image light, comprising:
a device substrate having first and second device substrate layers and a plurality of image pixels;
a vertical trench in the first device substrate layer; and
a light shield material formed in the vertical trench, wherein the light shield material blocks light from reaching a portion of the plurality of image pixels as the image sensor captures the image light, and wherein the portion of the plurality of image pixels includes at least one image pixel that is located under the vertical trench.

2. The image sensor defined in claim 1 further comprising:
a dielectric layer formed between the first device substrate layer and the light shield material formed in the vertical trench.

3. The image sensor defined in claim 2 wherein a portion of the dielectric layer further covers a horizontal portion of the first device substrate layer and wherein the light shield material covers the portion of the dielectric layer that covers the horizontal portion of the device substrate layer.

4. The image sensor defined in claim 3 further comprising a passivation layer formed on the light shield material.

5. The image sensor defined in claim 4 wherein the passivation layer further covers a portion of the dielectric layer that is not covered by the light shield material.

6. The image sensor defined in claim 5 wherein the plurality of image pixels are formed at an interface between the first and second device substrate layers.

7. The image sensor defined in claim 6 wherein the second device substrate layer comprises opposing first and second sides, wherein the interface between the first and second device substrate layers is on the first side, the image sensor further comprising:
a carrier structure attached to the second side.

8. The image sensor defined in claim 7, further comprising readout circuitry, wherein at least some of portion of the plurality of image pixels are electrically connected to the readout circuitry.

9. The image sensor defined in claim 8 wherein the first device substrate layer comprises silicon, wherein the second device substrate layer comprises an oxide material, and wherein the carrier structure comprises silicon.

10. The image sensor defined in claim 9 wherein the plurality of image pixels comprises an array of image pixels having first and second edges, wherein the first and second edge are substantially perpendicular, and wherein the portion of the plurality of image pixels comprises at least one row of image pixels adjacent to the first edge and at least one column of image pixels adjacent to the second edge.

11. A backside illuminated image sensor, comprising:
an array of image pixels that convert incoming light into electrical charge; and
a vertical light shield that shields a portion of the array of image pixels from illumination by the incoming light, wherein the vertical light shield has at least one horizontal portion that shields the portion of the array of image pixels from direct illumination by the incoming light and a vertical portion that shields the portion of the array of image pixels from illumination by reflected portions of the incoming light.

12. The backside illuminated image sensor defined in claim 11, comprising:
a silicon layer; and
a vertical trench formed in the silicon layer, wherein the vertical light shield is at least partially formed in the vertical trench.

13. The backside illuminated image sensor defined in claim 12 wherein the vertical light shield includes a dielectric layer formed on the silicon layer and light shield material formed on the dielectric layer.

14. The backside illuminated image sensor defined in claim 13 further comprising:
a passivation layer having a first portion formed on the dielectric layer and a second portion formed on the light shield material, wherein the vertical light shield includes the second portion of the passivation layer.

15. The backside illuminated image sensor defined in claim 14 further comprising:
an oxide material layer having opposing first and second sides; and
a silicon carrier, wherein the silicon layer is attached to the first side of the oxide material layer and wherein the silicon carrier is attached to the second side of the oxide material layer.

16. The backside illuminated image sensor defined in claim 14 wherein the light shield material comprises metal.

17. A method of forming a vertical light shield on a backside illuminated image sensor having oxide and silicon layers, comprising:
forming openings in the silicon layer;
depositing light shield material over a portion of the silicon layer so that light shield material fills at least some of the openings; and
forming additional openings in the light shield material.

18. The method defined in claim 17 further comprising:
before depositing the light shield material over the portion of the silicon layer, forming a dielectric layer on the portion of the silicon layer, wherein depositing the light shield material over the portion of the silicon layer comprises depositing the light shield material on the dielectric layer.

19. The method defined in claim 18 further comprising:
forming a passivation layer over the light shield material and the dielectric layer.

20. The method defined in claim 19 wherein the backside illumination image sensor comprises an array of image pixels, wherein the array of image pixels has first and second edges, wherein the first edge is substantially perpendicular to the second edge, and wherein forming the openings in the silicon layer comprises forming a vertical trench in the silicon layer having a first portion that is parallel to the first edge and a second portion that is parallel to the second edge.
